(19) United States
(12) Patent Application Publication
(10) Pub. No.: US 2023/0138593 A1
(43) Pub. Date: May 4, 2023

(54) SEMICONDUCTOR DEVICE AND METHOD FOR MANUFACTURING THE SAME

(71) Applicant: SK hynix Inc., Icheon (KR)

(72) Inventors: Ho Joon SONG, Icheon (KR); Jeong Hoon BAE, Icheon (KR); Jae Wan HWANG, Icheon (KR); Jung Won SEO, Icheon (KR); Jeong Ho YEON, Icheon (KR)

(21) Appl. No.: 17/736,979

(22) Filed: May 4, 2022

(30) Foreign Application Priority Data
Oct. 29, 2021 (KR) 10-2021-0147074

(51) Int. Cl. H01L 27/24; H01L 27/11507; H01L 27/11509; H01L 27/22

(52) U.S. Cl. CPC H01L 27/2463; H01L 27/11507; H01L 27/11509; H01L 27/222

(57) ABSTRACT

A method for manufacturing a semiconductor device may include: forming a plurality of stacked structures over a substrate, the substrate including one or more peripheral circuit regions and one or more cell regions, the stacked structures including first conductive lines and initial memory cells respectively disposed over the first conductive lines, each of the stacked structures extending in a first direction; forming a first insulating layer between the stacked structures; forming second conductive lines over the stacked structures and the first insulating layer, each of the second conductive lines extending in a second direction; forming memory cells by etching the initial memory cells exposed by the second conductive lines; forming a second insulating layer between the second conductive lines and between the memory cells; and removing the first conductive lines, the memory cells, and the second conductive lines in the peripheral circuit regions.

### CROSS-REFERENCE TO RELATED APPLICATION

This application claims priority under 35 U.S.C. § 119 to Korean Patent Application No. 10-2021-0147074 filed on Oct. 29, 2021, which is incorporated herein by reference in its entirety.

### BACKGROUND

### 1. Technical Field

This patent document relates to memory circuits or devices and their applications in electronic devices or systems.

### 2. Related Art

Recently, as electronic appliances trend toward miniaturization, low power consumption, high performance, multi-functionality, and so on, semiconductor devices capable of storing information in various electronic appliances such as a computer, a portable communication device, and so on have been demanded in the art, and research has been conducted for the semiconductor devices. Such semiconductor devices include semiconductor devices which can store data using a characteristic that they are switched between different resistance states according to an applied voltage or current, for example, an RRAM (resistive random access memory), a PRAM (phase change random access memory), an FRAM (ferroelectric random access memory), an MRAM (magnetic random access memory), an E-fuse, etc.

### SUMMARY

The disclosed technology in this patent document includes various embodiments of a semiconductor device capable of reducing or substantially preventing damage to a memory cell and a manufacturing method thereof.

In an embodiment, a method for manufacturing a semiconductor device, includes: forming a plurality of stacked structures over a substrate, the substrate including one or more peripheral circuit regions and one or more cell regions, the plurality of stacked structures including a plurality of first conductive lines and a plurality of initial memory cells respectively disposed over the first conductive lines, each of the stacked structures extending in a first direction; forming a first insulating layer between the stacked structures; forming a plurality of second conductive lines over the stacked structures and the first insulating layer, each of the second conductive lines extending in a second direction that crosses the first direction; forming memory cells by etching the initial memory cells exposed by the second conductive lines; forming a second insulating layer between the second conductive lines and between the memory cells; and removing the first conductive lines, the memory cells, and the second conductive lines in the peripheral circuit regions.

In another embodiment, a method for manufacturing a semiconductor device, includes: forming a plurality of stacked structures over a substrate, the substrate including one or more peripheral circuit regions and one or more cell regions, the plurality of stacked structures including a plurality of first conductive lines and a plurality of initial memory cells respectively disposed over the first conductive lines, each of the stacked structures extending in a first direction; forming a first insulating layer between the stacked structures; forming a plurality of second conductive lines over the stacked structures and the first insulating layer, each of the second conductive lines extending in a second direction that crosses the first direction, the second conductive lines overlapping the cell regions without overlapping the peripheral circuit regions; forming memory cells by etching the initial memory cells exposed by the second conductive lines; forming a second insulating layer between the second conductive lines and between the memory cells; and removing the first conductive lines in the peripheral circuit regions.

In another embodiment, a method for manufacturing a semiconductor device, includes: forming a plurality of stacked structures over a substrate, the substrate including one or more peripheral circuit regions and one or more cell regions, the plurality of stacked structures including a plurality of first conductive lines and a plurality of initial memory cells respectively disposed over the first conductive lines, each of the stacked structures extending in a first direction; forming a first insulating layer between the stacked structures; removing a group of the initial memory cells in a specific one of the peripheral circuit regions; filling a space formed by removing the group of the initial memory cells with a second insulating layer; forming a plurality of second conductive lines over the stacked structures, the first insulating layer, and the second insulating layer, each of the second conductive lines extending in a second direction that crosses the first direction; forming memory cells by etching the remaining ones of the initial memory cells exposed by the second conductive lines; forming a third insulating layer between the second conductive lines and between the memory cells; and removing the first conductive lines, the memory cells, and the second conductive lines in the peripheral circuit regions.

In another embodiment, a semiconductor device includes: a substrate including a plurality of cell regions arranged in a first direction and a second direction crossing the first direction, a first peripheral circuit region being positioned between a first adjacent pair of the cell regions arranged in the first direction, a second peripheral circuit region being positioned between a second adjacent pair of the cell regions arranged in the second direction; a first conductive line disposed over the substrate in a corresponding one of the cell regions and extending in the first direction; a second conductive line disposed over the first conductive line and extending in the second direction; a memory cell disposed at an intersection region of the first conductive line and the second conductive line and between the first conductive line and the second conductive line; and a dummy conductive line disposed in the second peripheral circuit region and adjacent to a corresponding one of the cell regions.

### BRIEF DESCRIPTION OF THE DRAWINGS

FIGS. 1A, 1B, 1C, 2A, 2B, 2C, 3A, 3B, 3C, 4A, 4B, 4C, 5A, 5B, and 5C are views illustrating a memory device according to an embodiment of the present disclosure, and a method for manufacturing the same.

FIG. 6 is a cross-sectional view illustrating a memory cell of FIGS. 5A to 5C according to an embodiment.

FIGS. 7A, 7B, 7C, 8A, 8B, 8C, 9A, 9B, 9C, 10A, 10B, and 10C are views illustrating a memory device according to another embodiment of the present disclosure, and a method for manufacturing the same.

FIGS. 11A, 11B, 11C, 12A, 12B, 12C, 13A, 13B, 13C, 14A, 14B, and 14C are views illustrating a memory device according to another embodiment of the present disclosure, and a method for manufacturing the same.

### DETAILED DESCRIPTION

Hereinafter, various embodiments of the disclosure will be described in detail with reference to the accompanying drawings.

The drawings are not necessarily drawn to scale. In some instances, proportions of at least some structures in the drawings may have been exaggerated in order to clearly illustrate certain features of the described embodiments. In presenting a specific example in a drawing or description having two or more layers in a multi-layer structure, the relative positioning relationship of such layers or the sequence of arranging the layers as shown reflects a particular implementation for the described or illustrated example and a different relative positioning relationship or sequence of arranging the layers may be possible. In addition, a described or illustrated example of a multi-layer structure might not reflect all layers present in that particular multilayer structure (e.g., one or more additional layers may be present between two illustrated layers). As a specific example, when a first layer in a described or illustrated multi-layer structure is referred to as being “on” or “over” a second layer or “on” or “over” a substrate, the first layer may be directly formed on the second layer or the substrate but may also represent a structure where one or more other intermediate layers may exist between the first layer and the second layer or the substrate.

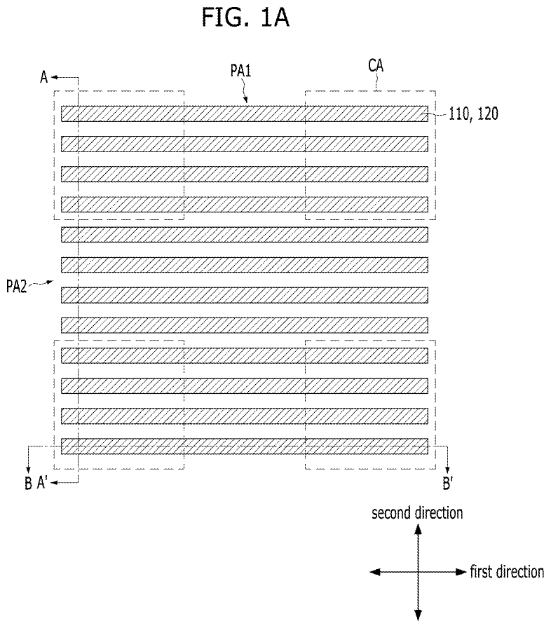

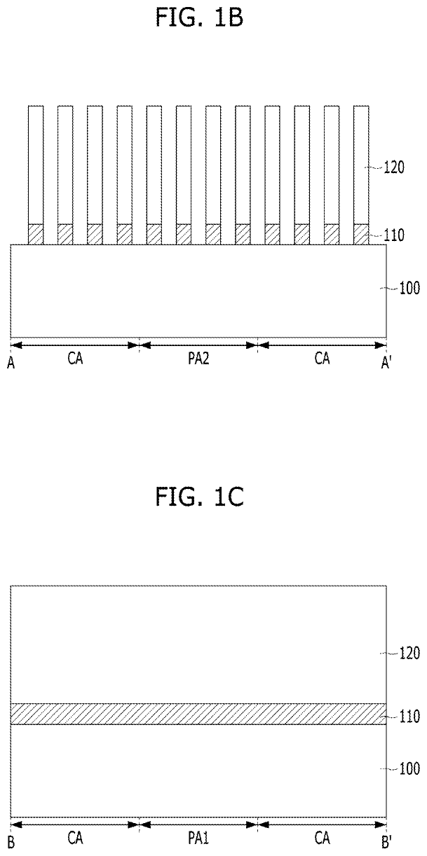

FIGS. 1A to 5C are views illustrating a memory device according to an embodiment of the present disclosure, and a method for manufacturing the same. FIGS. 1A, 2A, 3A, 4A, and 5A show planar views, FIGS. 1B, 2B, 3B, 4B, and 5B show cross-sectional views taken along a line A-A′ of FIGS. 1A, 2A, 3A, 4A, and 5A, respectively, and FIGS. 1C, 2C, 3C, 4C, and 5C show cross-sectional views taken along a line B-B′ of FIGS. 1A, 2A, 3A, 4A, and 5A, respectively. For convenience of description, conductive lines and memory cells are illustrated in the planar views of FIGS. 1A, 2A, 3A, 4A, and 5A, and an insulating layer filling the spaces therebetween is omitted.

Hereinafter, a manufacturing method will be first described.

Referring to FIGS. 1A, 1B, and 1C, a substrate 100 may be provided. The substrate 100 may include a semiconductor material such as silicon. In addition, a desired lower structure (not shown) may be formed in the substrate 100. For example, an integrated circuit for driving conductive lines to be described later may be formed in the substrate 100.

A cell region CA and peripheral circuit regions PA1 and PA2 may be defined in the substrate 100. The cell region CA may be a region in which a plurality of memory cells are arranged, and the peripheral circuit regions PA1 and PA2 may be regions in which various components other than the memory cells are disposed. For example, in the peripheral circuit regions PA1 and PA2, a contact electrically connected to the integrated circuit in the substrate 100, an align key, or the like may be disposed. In the embodiment of FIGS. 1A, 1B, and 1C, four cell regions CA may be arranged to be spaced apart from each other in a 2*2 matrix shape along a first direction and a second direction crossing the first direction, and peripheral circuit regions PA1 and PA2 may be formed between these cell regions CA in a cross shape or a grid shape. For convenience of description, a region located between the two cell regions CA arranged in the first direction and extending in the second direction may be referred to as a first peripheral circuit region PA1, and a region located between the two cell regions CA arranged in the second direction and extending in the first direction may be referred to as a second peripheral circuit region PA2. For example, the first peripheral circuit region PA1 may include a first region between a first adjacent pair of cell regions CA arranged in the first direction, a second region between a second adjacent pair of cell regions CA arranged in a diagonal direction, and a third region between a third adjacent pair of cell regions CA arranged in the first direction, and the first, second, and third regions are substantially aligned in the second direction. Accordingly, the first peripheral circuit region PA1 and the second peripheral circuit region PA2 may have an overlapping region, and the overlapping region may not be located between the cell regions CA in the first direction and the second direction. The overlapping region may be located between the cell regions CA in a diagonal direction. However, embodiments of the present disclosure are not limited thereto, and the number, arrangement, shape, or the like of the cell regions CA and the peripheral circuit regions PA1 and PA2 may vary according to embodiments.

Subsequently, a stacked structure of a first conductive line (or an initial first conductive line) 110 and an initial memory cell 120 may be formed over the substrate 100. The first conductive line 110 and the initial memory cell 120 may be formed by depositing a conductive layer for forming the first conductive line 110 and a material layer for forming the initial memory cell 120 over the substrate 100, and etching the conductive layer and the material layer using a line-shaped mask pattern (not shown) extending in the first direction as an etching barrier. For example, a plurality of stacked structure may be formed over the substrate 100, the plurality of stacked structure including a plurality of first conductive lines 110 and a plurality of initial memory cells 120 respectively disposed over the first conductive lines 110. The plurality of first conductive lines 110 and the plurality of initial memory cells 120 may be formed by depositing a conductive layer and a material layer over the substrate 100, and etching the conductive layer and the material layer using a mask pattern (not shown) with a plurality of line-shaped patterns each extending in the first direction as an etching barrier.

The stacked structure of the first conductive line 110 and the initial memory cell 120 may have a line shape extending in the first direction in a planar view, and may cross the two cell regions CA arranged in the first direction and the first peripheral circuit region PA1 therebetween.

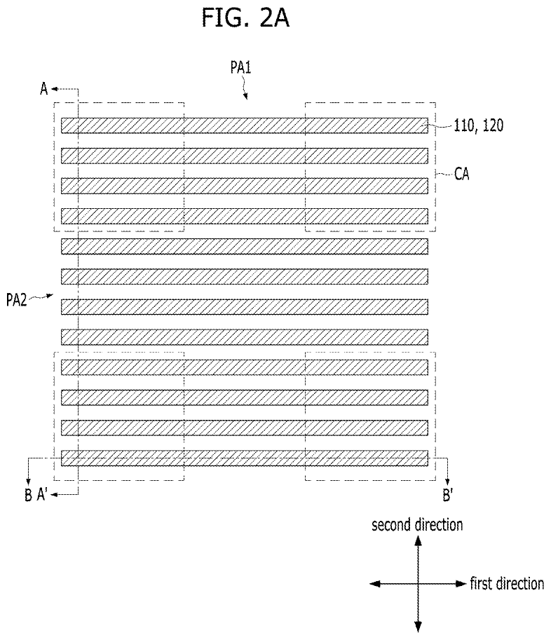

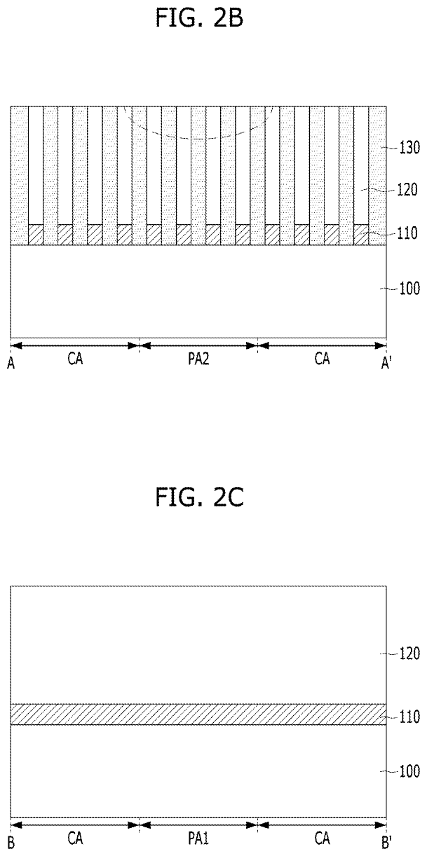

Also, a plurality of the stacked structures including the first conductive lines 110 and the initial memory cells 120 may be arranged to be spaced apart from each other in the second direction. In this case, the plurality of stacked structures including the first conductive lines 110 and the initial memory cells 120 may exist in the cell regions CA as well as in the second peripheral circuit region PA2 in the second direction. The stacked structures of the first conductive lines 110 and the initial memory cells 120 in the second peripheral circuit region PA2 may be dummy structures that do not perform any significant electrical function. Such a dummy may be formed in order to substantially prevent an attack on the initial memory cell 120 in the cell region CA and loss of the initial memory cell 120 therefrom, during a planarization process described later (refer to FIG. 2B). This will be described in a related paragraph in more detail.

In the second direction, the stacked structures of the first conductive lines 110 and the initial memory cells 120 may be arranged at substantially constant intervals. That is, in the second direction, a distance between the stacked structures of the first conductive lines 110 and the initial memory cells 120 in the cell region CA may be substantially the same as a distance between the stacked structures of the first conductive lines 110 and the initial memory cells 120 in the second peripheral circuit region PA2.

The first conductive line 110 may include various conductive materials, for example, a metal such as platinum (Pt), tungsten (W), aluminum (Al), copper (Cu), and tantalum (Ta), a metal nitride such as titanium nitride (TiN) and tantalum nitride (TaN), or a combination thereof, and may have a single-layered structure or a multi-layered structure.

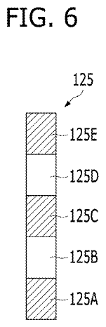

The initial memory cell 120 may include various materials capable of performing a data storage function. As an example, the initial memory cell 120 may include a variable resistance material that switches between different resistance states according to an applied voltage or current. The variable resistance material may include at least one of materials used for an RRAM, a PRAM, an MRAM, an FRAM, or the like, that is, a metal oxide such as a perovskite-based oxide or a transition metal oxide, a phase change material such as a chalcogenide-based material, a ferromagnetic material, a ferroelectric material, or the like. Also, the initial memory cell 120 may have a single-layered structure or a multi-layered structure. The initial memory cell 120 may be patterned in a subsequent process to be transformed into a pillar-shaped memory cell, and an example of such a memory cell will be described later in more detail with reference to FIG. 6.

Referring to FIGS. 2A, 2B, and 2C, a first insulating layer (or initial first insulating layer) 130 filling a space between the stacked structures of the first conductive lines 110 and the initial memory cells 120 may be formed over the substrate 100. In an embodiment, the first insulating layer 130 may be formed between the stacked structures of the first conductive lines 110 and the initial memory cells 120. For example, the first insulating layer 130 may include a plurality of portions, each of which may fill a space between an adjacent pair of the stacked structures that include the first conductive lines 110 and the initial memory cells 120, respectively.

The first insulating layer 130 may be formed by forming an insulating material with a thickness to sufficiently cover the stacked structure of the first conductive line 110 and the initial memory cell 120 over the substrate 100, and performing a planarization process until the upper surface of the initial memory cell 120 is exposed. For example, the first insulating layer 130 may be formed by forming an insulating material with a thickness to sufficiently cover the plurality of stacked structures of the first conductive lines 110 and the initial memory cells 120 over the substrate 100, and performing a planarization process until the upper surfaces of the initial memory cells 120 are exposed.

The first insulating layer 130 may include various insulating materials such as an oxide (e.g., silicon oxide), a nitride (e.g., silicon nitride), or a combination thereof. The planarization process may include a polishing process such as chemical mechanical polishing (CMP) or an etch-back process.

If the stacked structure of the first conductive line 110 and the initial memory cell 120 does not exist in the second peripheral circuit region PA2, the first insulating layer 130 of the second peripheral circuit region PA2 may be depressed due to a difference in pattern density between the cell region CA and the second peripheral circuit region PA2 during the planarization process, and thus, an upper portion of one of the initial memory cells 120 of the cell region CA, which is relatively adjacent to the second peripheral circuit region PA2, may be lost (see dotted line).

However, in the embodiment of FIGS. 2A to 2C, by disposing the stacked structure of the first conductive line 110 and the initial memory cell 120 in the second peripheral circuit region PA2 like the cell region CA, a difference in pattern density between the cell region CA and the second peripheral circuit region PA2 may be reduced and/or substantially eliminated. In an embodiment, a pattern density may be defined in a specific region (e.g., the cell region CA) as a ratio of a total area of portions of the initial memory cells 120 in the specific region to a total area of portions of the first insulating layer 130 in the specific region, when seen in a top view of the structure shown in FIGS. 2A to 2C. As a result, the loss of the initial memory cell 120 may be substantially prevented. The upper surfaces of the initial memory cells 120 may be positioned at substantially the same height from the substrate 100, and may form a substantially flat surface with the upper surface of the first insulating layer 130 in the cell region CA and the second peripheral circuit region PA2. In an embodiment, a surface formed by the upper surfaces of the initial memory cells 120 and the upper surface of the first insulating layer 130 in the cell regions CA and the second peripheral circuit region PA2 may be substantially flat such that a maximum difference in height of the surface may not be greater than 5%, 3%, or 1% of an average height of the surface. In another embodiment, the maximum difference in height of the surface may not be greater than 0.5%, 0.3%, or 0.1% of the average height of the surface.

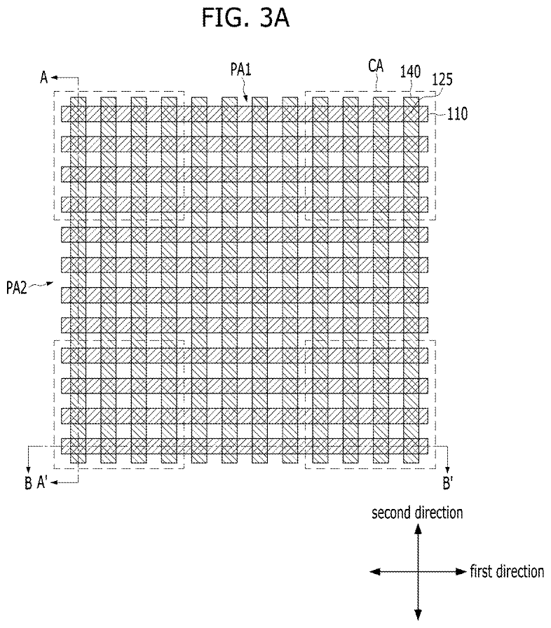

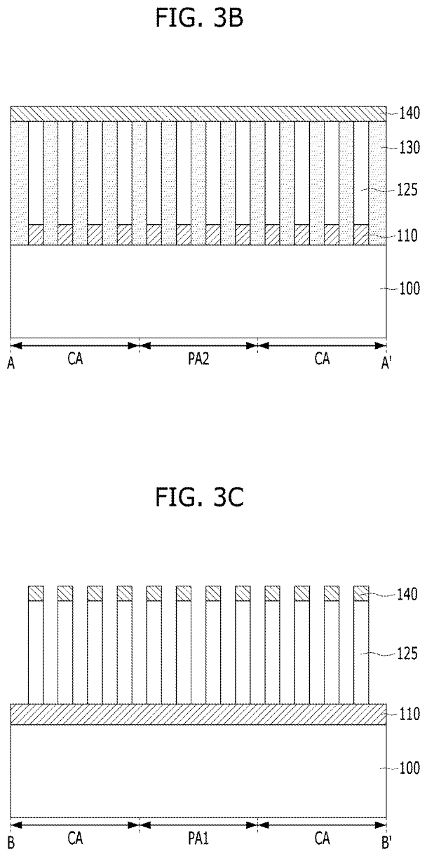

Referring to FIGS. 3A, 3B, and 3C, second conductive lines (or initial second conductive lines) 140 may be formed over the initial memory cells 120 and the first insulating layer 130, and then, the initial memory cells 120 exposed by the second conductive lines 140 may be etched to form memory cells 125. The second conductive lines 140 and the memory cells 125 may be formed by depositing a conductive layer for forming the second conductive lines 140 over the initial memory cells 120 and the first insulating layer 130, and etching the conductive layer and the initial memory cells 120 using a mask pattern (not shown) with a plurality of line-shaped patterns each extending in the second direction as an etching barrier.

The second conductive line 140 may have a line shape extending in the second direction in a planar view, and may cross the two cell regions CA arranged in the second direction and the second peripheral circuit region PA2 therebetween.

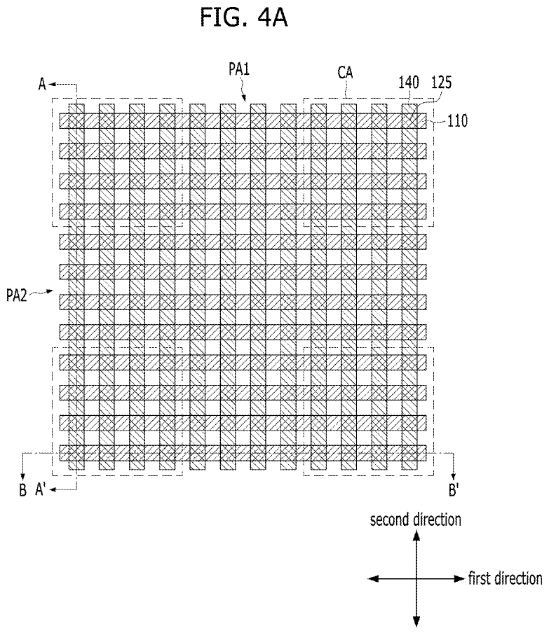

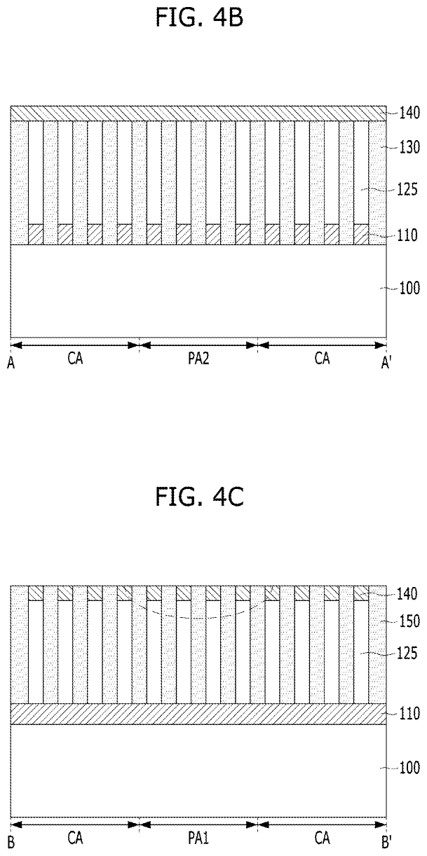

Also, the second conductive lines 140 may be arranged to be spaced apart from each other in the first direction. In this case, the second conductive lines 140 may exist not only in the cell regions CA but also in the first peripheral circuit region PA1 in the first direction. The second conductive lines 140 of the first peripheral circuit region PA1 may be dummy structures that do not perform any significant electrical function. These dummy structures may be formed to substantially prevent an attack on the memory cell 125 in the cell region CA during a planarization process to be described later (refer to FIG. 4C). This will be described in a related paragraph in more detail.

In the first direction, the plurality of second conductive lines 140 may be arranged at substantially constant intervals. That is, in the first direction, a distance between the second conductive lines 140 in the cell region CA may be substantially the same as a distance between the second conductive lines 140 in the first peripheral circuit region PA1.

The second conductive line 140 may include various conductive materials, for example, a metal such as platinum (Pt), tungsten (W), aluminum (Al), copper (Cu), and tantalum (Ta), a metal nitride such as titanium nitride (TiN) and tantalum nitride (TaN), or a combination thereof, and may have a single-layered structure or a multi-layered structure.

The memory cell 125 may have an island shape in a planar view while being positioned at an intersection region of the first conductive line 110 and the second conductive line 140. The memory cells 125 may be arranged in a matrix form along the first direction and the second direction. In the first direction, both sidewalls of the memory cell 125 may be aligned with both sidewalls of the second conductive line 140, and in the second direction, both sidewalls of the memory cell 125 may be aligned with both sidewalls of the first conductive line 110. Specifically, a first pair of sidewalls of the memory cell 125 arranged in the first direction may be substantially aligned with corresponding sidewalls of the second conductive line 140, and a second pair of sidewalls of the memory cell 125 arranged in the second direction may be substantially aligned with corresponding sidewalls of the first conductive line 110. As described above, since the first conductive lines 110 are disposed in the second peripheral circuit region PA2 and the second conductive lines 140 are disposed in the first peripheral circuit region PA1, the memory cells 125 may be arranged in the first and second peripheral circuit regions PA1 and PA2 as well as the cell regions CA. However, since the first conductive lines 110 of the second peripheral circuit region PA2 correspond to dummy structures and the second conductive lines 140 of the first peripheral circuit region PA1 correspond to dummy structures, the memory cells 125 in the first and second peripheral circuit regions PA1 and PA2 may also correspond to dummy structures.

Meanwhile, in the etching process of the initial memory cell 120, the first insulating layer (or first initial insulating layer) 130 exposed by the second conductive lines 140 may also be etched. As a result, the first insulating layers 130, which have been etched, may overlap the second conductive line 140 under the second conductive line 140, and may have a pillar shape alternately arranged with the pillar-shaped memory cells 125 in the second direction.

Referring to FISG. 4A, 4B, and 4C, a second insulating layer (or initial second insulating layer) 150 filling spaces between the memory cells 125, between the first insulating layers 130, and between the second conductive lines 140 may be formed over the substrate 100.

The second insulating layer 150 may be formed by forming an insulating material with a thickness to sufficiently cover the second conductive line 140 over the substrate 100, and performing a planarization process until the upper surface of the second conductive line 140 is exposed. For example, the second insulating layer 150 may be formed by forming an insulating material with a thickness to sufficiently cover the second conductive lines 140 over the substrate 100, and performing a planarization process until upper surfaces of the second conductive lines 140 are exposed. The second insulating layer 150 may include various insulating materials such as an oxide (e.g., silicon oxide), a nitride (e.g., silicon nitride), or a combination thereof. The second insulating layer 150 may be formed of the same material as the first insulating layer 130. The planarization process may include a polishing process such as CMP or an etch-back process.

If the stacked structure of the second conductive line 140 and the memory cell 125 does not exist in the first peripheral circuit region PA1, the second insulating layer 150 of the first peripheral circuit region PA1 may be depressed due to a difference in pattern density between the cell region CA and the first peripheral circuit region PA1 during the planarization process, and thus, at least a portion of one of the second conductive lines 140 of the cell region CA, which is relatively adjacent to the first peripheral circuit region PA1, may be lost (see dotted line). If the loss of the second conductive line 140 increases, the memory cell 125 may also be lost.

However, in the embodiment of FIGS. 4A to 4C, by disposing the stacked structure of the second conductive line 140 and the memory cell 125 in the first peripheral circuit region PA1 like the cell region CA, a difference in pattern density between the cell region CA and the first peripheral circuit region PA1 may be reduced and/or substantially eliminated. Accordingly, the loss of the memory cell 125 may be substantially prevented by reducing and/or preventing the loss of the second conductive line 140. The upper surfaces of the second conductive lines 140 may be positioned at substantially the same height from the substrate 100, and may form a substantially flat surface with the upper surface of the second insulating layer 150 in the cell region CA and the first peripheral circuit region PA1. In an embodiment, a surface formed by the upper surfaces of the second conductive lines 140 and the upper surface of the second insulating layer 150 in the cell regions CA and the first peripheral circuit region PA1 therebetween may be substantially flat such that a maximum difference in height of the surface may not be greater than 5%, 3%, or 1% of an average height of the surface. In another embodiment, the maximum difference in height of the surface may not be greater than 0.5%, 0.3%, or 0.1% of the average height of the surface.

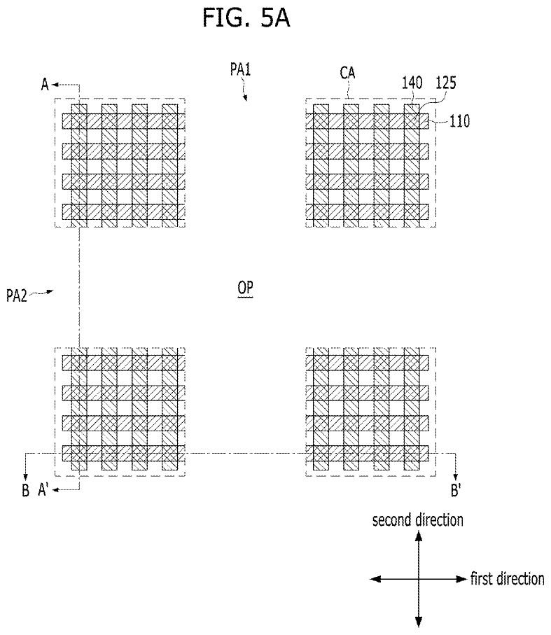

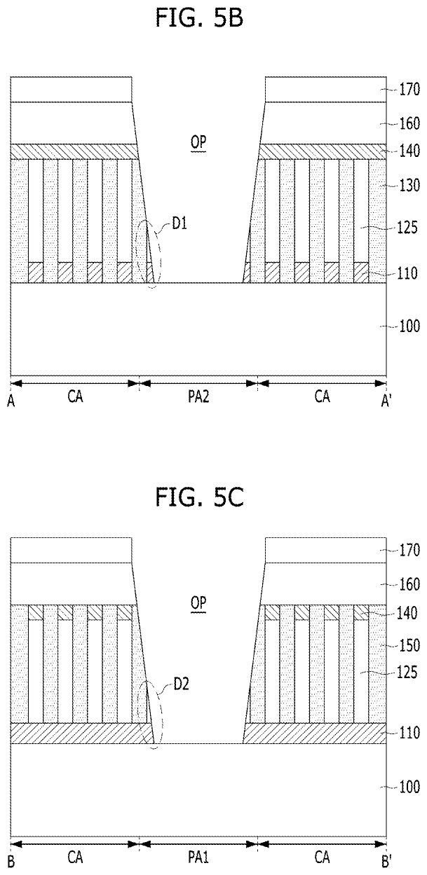

Referring to FIGS. 5A, 5B, and 5C, a third insulating layer 160 may be formed over the second conductive lines 140 and the second insulating layer 150. Then, a mask pattern 170 covering the cell region CA and exposing the first and second peripheral circuit regions PA1 and PA2 may be formed over the third insulating layer 160. Then, the third insulating layer 160, the second conductive lines 140, the second insulating layer 150, the memory cells 125, the first insulating layer 130, and the first conductive lines 110 may be removed using the mask pattern 170 as an etching barrier. Accordingly, an opening OP exposing the substrate 100 may be formed in the first and second peripheral circuit regions PA1 and PA2. As a result of this process, the first conductive lines 110, the second conductive lines 140, and the memory cells 125 may exist in the cell region CA while being removed from the first and second peripheral circuit regions PA1 and PA2. The first conductive line 110 may be cut in the first direction, and the second conductive line 140 may be cut in the second direction. For example, portions of the initial first conductive lines 110 in the first and second peripheral circuit regions PA1 and PA2 may be removed to make the first conductive lines 110 remain substantially in the cell regions CA, and portions of the initial second conductive lines 140 in the first and second peripheral circuit regions PA1 and PA2 may be removed to make the second conductive lines 140 remain substantially in the cell regions CA.

The third insulating layer 160 may include various insulating materials such as an oxide (e.g., silicon oxide), a nitride (e.g., silicon nitride), or a combination thereof. The third insulating layer 160 may be formed of the same material as the first insulating layer 130, or the second insulating layer 150, or both.

The opening OP may be formed by an anisotropic etching method such as dry etching. Due to the characteristics of the anisotropic etching process, the opening OP may have a shape that becomes narrower from top to bottom. Accordingly, the opening OP may have an inclined sidewall. This may be because, in the anisotropic etching, byproducts generated as the etching process progresses are accumulated on the etched surface. In this case, the third insulating layer 160, the second conductive line 140, the second insulating layer 150, the memory cell 125, the first insulating layer 130, and the first conductive line 110 in the first and second peripheral circuit regions PA1 and PA2 may not be completely removed, and portions thereof may remain at the edges of the first and second peripheral circuit regions PA1 and PA2 adjacent to the cell region CA. This is not clearly shown in the planar view of FIG. 5A, but is shown in FIGS. 5B and 5C as an example.

In an embodiment, at least one of the first conductive lines 110 disposed in the second peripheral circuit region PA2 and adjacent to the cell region CA may be partially removed to make a portion of the at least one of the first conductive lines 110 remain in the second peripheral circuit region PA2. For example, as shown in FIG. 5B, in the second direction, a portion of the first conductive line 110, which is closest to the cell region CA, among the first conductive lines 110 of the second peripheral circuit region PA2 may remain in the second peripheral circuit region PA2 (as indicated in a dashed oval D1). Furthermore, a portion of the memory cell 125 may also remain over the portion of the first conductive line 110 of the second peripheral circuit region PA2 (as indicated in the dashed oval D1). The portion of the first conductive line 110, or the portion of the memory cell 125, or both may be referred to as a dummy pattern. For example, the portion of the first conductive line 110 may be referred to as a dummy conductive line, and the portion of the memory cell 125 may be referred to as a dummy memory cell. In the second direction, a width of the portion of the first conductive line 110 and a width of the portion of the memory cell 125 in the second peripheral circuit region PA2 may be smaller than a width of the first conductive line 110 and a width of the memory cell 125 in the cell region CA. In addition, since the opening OP has an inclined sidewall, in the second direction, each of the portion of the first conductive line 110 and the portion of the memory cell 125 in the second peripheral circuit region PA2 may have an inclined sidewall.

Also, in an embodiment, portions of the first conductive lines 110 in the first peripheral circuit region PA1 may be removed. For example, as shown in FIG. 5C, in the first direction, the first conductive line 110 may have an end portion protruding toward the first peripheral circuit region PA1 (as indicated in a dashed oval D2). Furthermore, a portion of the memory cell 125 may also remain over the end portion of the first conductive line 110 of the first peripheral circuit region PA1 (as indicated in the dashed ovalD2). In the first direction, the end portion of the first conductive line 110 may have an inclined sidewall. In the first direction, the portion of the memory cell 125 in the first peripheral circuit region PA1 may have an inclined sidewall, and may have a smaller width than the memory cell 125 of the cell region CA.

Although not shown, as subsequent processes, an insulating material filling the opening OP may be formed, and then, a contact formation process may be further performed.

The memory device shown in FIGS. 5A, 5B, and 5C may be manufactured by the process described above.

Referring back to FIGS. 5A, 5B, and 5C, the memory device may include the substrate 100 in which the cell regions CA and the peripheral circuit regions PA1 and PA2 are defined, and the first conductive lines 110, the second conductive lines 140, and the memory cells 125 that are disposed in the cell regions CA. The first conductive line 110 may extend in the first direction, the second conductive line 140 may extend in the second direction over the first conductive line 110, and the memory cell 125 may be disposed at the intersection region of the first conductive line 110 and the second conductive line 140 between them.

The first conductive line 110, the memory cell 125, and the second conductive line 140 may be removed from the peripheral circuit regions PA1 and PA2. However, a portion of the first conductive line 110, or a portion of the memory cell 125, or both may remain at the edge of each of the peripheral circuit regions PA1 and PA2, which is adjacent to the cell region CA. In other words, portions of the first conductive line 110, the memory cell 125, and the second conductive line 140 may be substantially removed from the peripheral circuit regions PA1 and PA2. The portion of the first conductive line 110 and the portion of the memory cell 125 partially remaining in each of the peripheral circuit regions PA1 and PA2 have already been described in the process of explaining the manufacturing method, and thus detailed description thereof will be omitted for the interest of brevity.

In a memory device and a manufacturing method thereof according to embodiments of the present disclosure, the stacked structure of the first conductive line 110 and the initial memory cell 120 may be formed up to the second peripheral circuit region PA2, so that it may be possible to substantially prevent the loss of the initial memory cell 120 during the planarization process. Specifically, referring back to FIGS. 2A to 2C, since the stacked structure of the initial first conductive lines 110 and the initial memory cells 120 may be formed in the second peripheral circuit region PA2 as well as the cell regions CA, a difference in pattern density between the second peripheral circuit region PA2 and the cell regions CA may be sufficiently small to substantially prevent the loss of the initial memory cell 120 during the planarization process to form the first insulating layer 130.

Furthermore, the stacked structure of the second conductive line 140 and the memory cell 125 may be formed up to the first peripheral circuit region PA1, so that it may be possible to further prevent the loss of the memory cell 125 during the planarization process. Specifically, referring back to FIGS. 4A to 4C, since the stacked structure of the initial second conductive lines 140 and the memory cells 125 may be formed in the first peripheral circuit region PA1 as well as the cell regions CA, a difference in pattern density between the first peripheral circuit region PA1 and the cell regions CA may be sufficiently small to substantially prevent the loss of the memory cell 125 during the planarization process to form the second insulating layer 150.

FIG. 6 is a cross-sectional view illustrating an example of a memory cell of FIGS. 5A to 5C.

Referring to FIG. 6, the memory cell 125 may include a multi-layered structure including a lower electrode layer 125A, a selection element layer 125B, an intermediate electrode layer 125C, a variable resistance layer 125D, and an upper electrode layer 125E.

The lower electrode layer 125A and the upper electrode layer 125E may be positioned at both ends of the memory cell 125, for example, at lower and upper ends, respectively, and may function to transmit a voltage or current required for the operation of the memory cell 125. The intermediate electrode layer 125C may function to electrically connect the selection element layer 125B and the variable resistance layer 125D while physically separating them. The lower electrode layer 125A, the intermediate electrode layer 125C, or the upper electrode layer 125E may include various conductive materials, for example, a metal such as platinum (Pt), tungsten (W), aluminum (Al), copper (Cu), and tantalum (Ta), a metal nitride such as titanium nitride (TiN) and tantalum nitride (TaN), or a combination thereof. Alternatively, the lower electrode layer 125A, the intermediate electrode layer 125C, or the upper electrode layer 125E may include a carbon electrode.

The selection element layer 125B may function to substantially prevent current leakage that may occur between the memory cells 125 sharing the first conductive line 110 or the second conductive line 140. To this end, the selection element layer 125B may have a threshold switching characteristic, that is, a characteristic for substantially blocking or limiting current when a magnitude of an applied voltage is less than a predetermined threshold value and for allowing current to abruptly increase above the threshold value. The threshold value may be referred to as a threshold voltage, and the selection element layer 125B may be implemented in a turned-on state or a turned-off state based on the threshold voltage. The selection element layer 125B may include a diode, an ovonic threshold switching (OTS) material such as a chalcogenide-based material, a mixed ionic electronic conducting (MIEC) material such as a metal-containing chalcogenide-based material, a metal insulator transition (MIT) material such as NbO₂, VO₂, or the like, or a tunneling insulating layer having a relatively wide band gap, such as SiO₂, Al₂O₃, or the like.

The variable resistance layer 125D may be a part that stores data in the memory cell 125. To this end, the variable resistance layer 125D may have a variable resistance characteristic of switching between different resistance states according to an applied voltage. The variable resistance layer 125D may have a single-layered structure or a multi-layered structure including at least one of materials used for an RRAM, a PRAM, an MRAM, an FRAM, or the like, that is, a metal oxide such as a perovskite-based oxide or a transition metal oxide, a phase change material such as a chalcogenide-based material, a ferromagnetic material, a ferroelectric material, or the like.

However, the layered-structure of the memory cell 125 is not limited to the embodiment shown in FIG. 6. When the memory cell 125 is a variable resistance element, the stacking order of the layers included in the memory cell 125 may be changed or at least one of the stacked layers of the memory cell 125 may be omitted as long as the memory cell 125 includes the variable resistance layer 125D which is essential for data storage. As an example, one or more of the lower electrode layer 125A, the selection element layer 125B, the intermediate electrode layer 125C, and the upper electrode layer 125E may be omitted. Alternatively, as an example, the positions of the selection element layer 125B and the variable resistance layer 125D may be reversed with each other. Alternatively, as an example, one or more layers (not shown) may be added to the memory cell 125 to improve fabricating processes or characteristics of the memory cell 125.

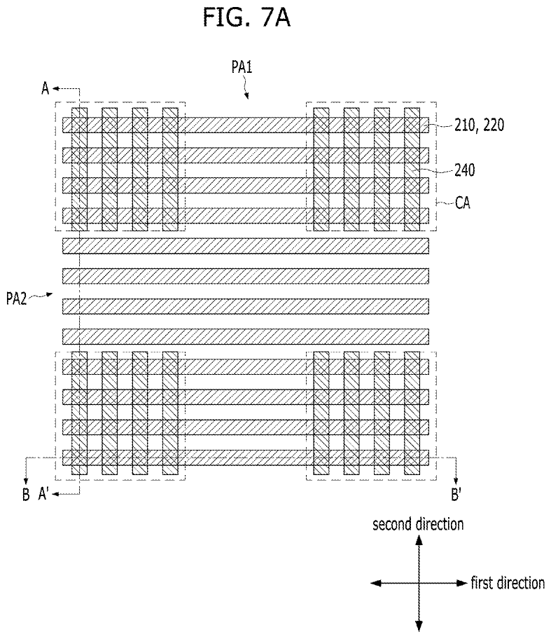

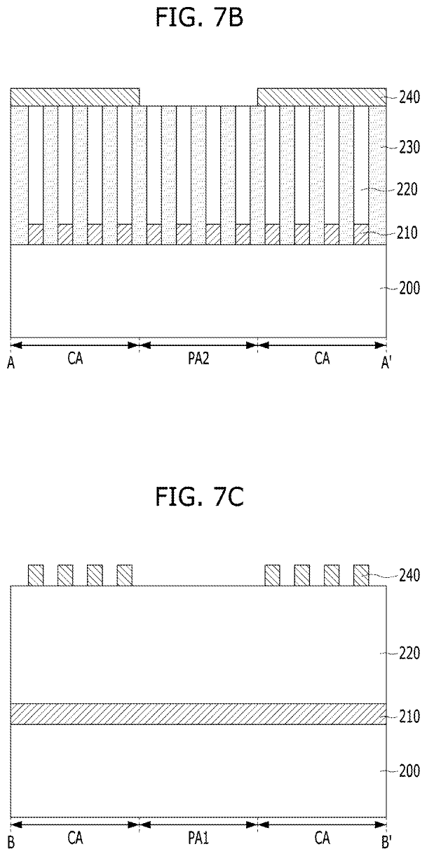

FIGS. 7A to 10C are views illustrating a memory device according to another embodiment of the present disclosure, and a method for manufacturing the same. FIGS. 7A, 8A, 9A, and 10A show planar views, FIGS. 7B, 8B, 9B, and 10B show cross-sectional views taken along a line A-A′ of FIGS. 7A, 8A, 9A, and 10A, respectively, and FIGS. 7C, 8C, 9C, and 10C show cross-sectional views taken along a line B-B′ of FIGS. 7A, 8A, 9A, and 10A, respectively. For convenience of description, conductive lines and memory cells are illustrated in the planar views of FIGS. 7A, 8A, 9A, and 10A, and an insulating layer filling the spaces therebetween is omitted. Differences from the above-described embodiment will be mainly described.

Referring to FIGS. 7A, 7B, and 7C, by performing substantially the same processes as the processes of FIGS. 1A to 2C described above, a structure in which stacked structures of first conductive lines (or initial first conductive lines) 210 and initial memory cells 220 and a first insulating layer (or initial first insulating layer) 230 filled between the stacked structures are formed over the substrate 200 including a cell region CA, a first peripheral circuit region PA1, and a second peripheral circuit region PA2 may be provided. In this case, damage to the initial memory cell 220 may be substantially prevented during the planarization process for forming the first insulating layer 230.

Subsequently, second conductive lines 240 may be formed over the initial memory cells 220 and the first insulating layer 230. The second conductive lines 240 may have a line shape extending in the second direction and may be arranged to be spaced apart from each other in the first direction.

In this case, the second conductive lines 240 may be formed in the cell region CA and may not exist in the first and second peripheral circuit regions PA1 and PA2, unlike the above-described embodiment.

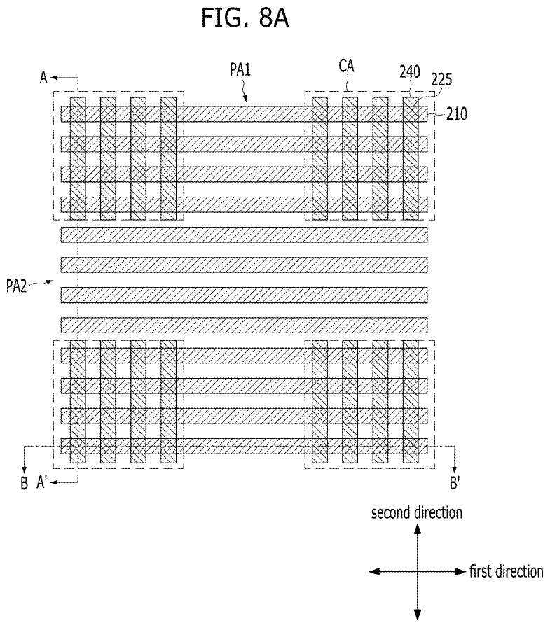

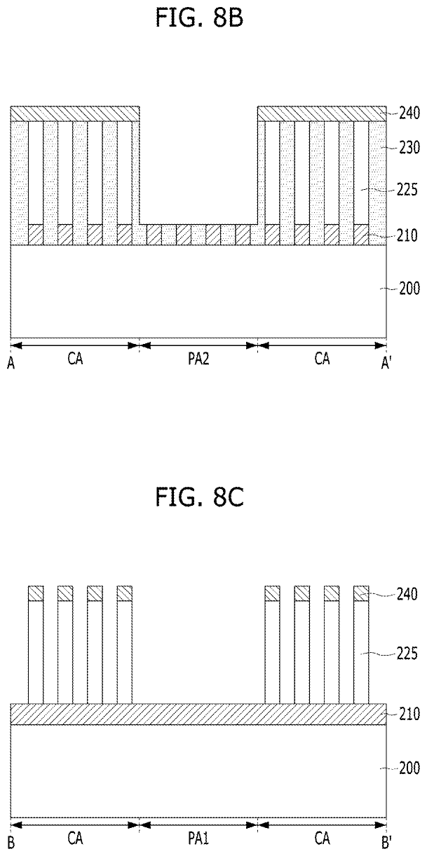

Referring to FIGS. 8A, 8B, and 8C, memory cell 225 may be formed by etching the initial memory cells 220 exposed by the second conductive lines 240.

The memory cell 225 may have an island shape in a planar view while being positioned at the intersection region of the first conductive line 210 and the second conductive line 240. The memory cells 225 may be arranged in a matrix form along the first direction and the second direction. In the first direction, both sidewalls of the memory cell 225 may be aligned with both sidewalls of the second conductive line 240, and in the second direction, both sidewalls of the memory cell 225 may be aligned with both sidewalls of the first conductive line 210. Specifically, a first pair of sidewalls of the memory cell 225 arranged in the first direction may be substantially aligned with corresponding sidewalls of the second conductive line 240, and a second pair of sidewalls of the memory cell 225 arranged in the second direction may be substantially aligned with corresponding sidewalls of the first conductive line 210.

As described above, since the first conductive lines 210 are located in the first and second peripheral circuit regions PA1 and PA2, while the second conductive lines 240 are located only in the cell is region CA, the memory cells 225 may also be disposed only in the cell region CA.

Meanwhile, in the etching process of the initial memory cells 220, the first insulating layer 230 exposed by the second conductive lines 240 may also be etched. As a result, only the first conductive lines 210 and the first insulating layer (or intermediate first insulating layer) 230 therebetween may exist in the first and second peripheral circuit regions PA1 and PA2, and an empty space may be positioned thereon.

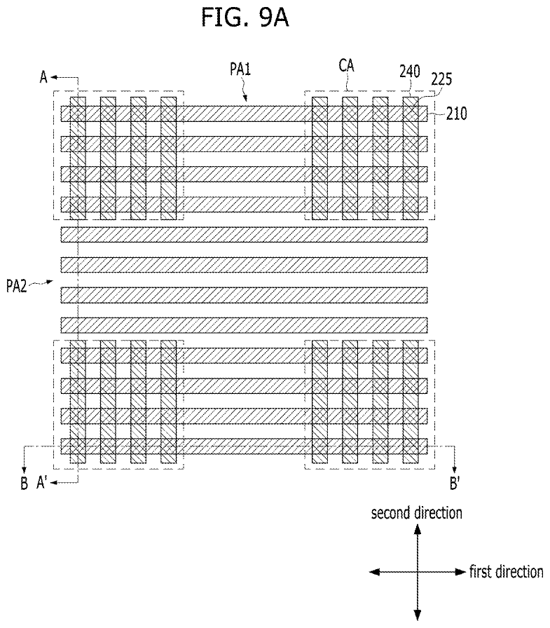

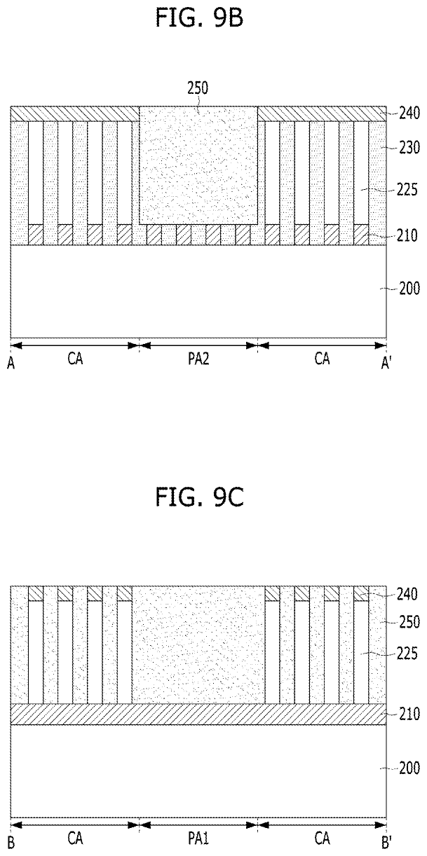

Referring to FIGS. 9A, 9B, and 9C, a second insulating layer (or initial second insulating layer) 250 filling spaces between the memory cells 225, between the first insulating layers 230, and between the second conductive lines 240 may be formed over the substrate 200. The second insulating layer 250 may fill the empty space of the first and second peripheral circuit regions PA1 and PA2.

The second insulating layer 250 may be formed by forming an insulating material with a thickness to sufficiently cover the second conductive line 240 over the substrate 200, and performing a planarization process until the upper surface of the second conductive line 240 is exposed.

Since the first conductive lines 210 and the first insulating layer 230 therebetween exist in the first and second peripheral circuit regions PA1 and PA2, the degree of depression of the second insulating layer 250 and the degree of loss of the second conductive line 240 therefrom may be reduced, compared to a case in which no pattern is present in the first and second peripheral circuit regions PA1 and PA2. Specifically, since the initial first conductive lines 210 and the first insulating layer 230 therebetween may be formed in the first and second peripheral circuit regions PA1 and PA2, the degree of depression of the second insulating layer 250 during the planarization process to form the second insulating layer 250 may be reduced compared to when the initial first conductive lines 210 are not formed in the first and second peripheral circuit regions PA1 and PA2 in a conventional manufacturing process. As a result, the degree of loss of the second conductive lines 240 may be reduced in the embodiment shown in FIGS. 9A to 9C compared to that in the conventional manufacturing process. Since the loss of the second conductive line 240 is reduced, the possibility of loss of the memory cell 225 may also be reduced.

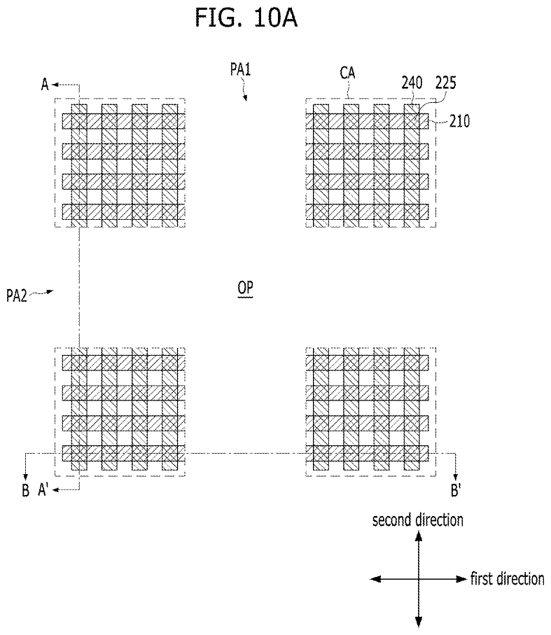

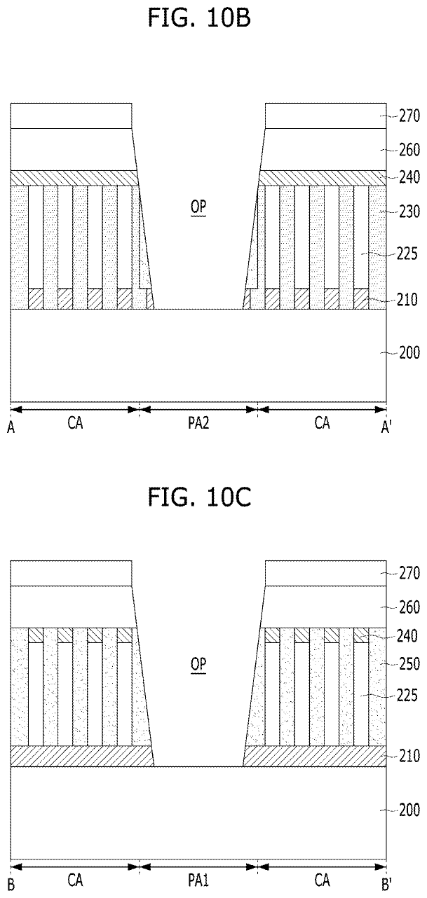

Referring to FIGS. 10A, 10B, and 10C, a third insulating layer (or an initial third insulating layer) 260 may be formed over the second conductive lines 240 and the second insulating layer 250. Then, a mask pattern 270 covering the cell regions CA and exposing the first and second peripheral circuit regions PA1 and PA2 may be formed over the third insulating layer 260. Then, the third insulating layer 260, the second conductive line 240, the second insulating layer 250, the memory cell 225, the first insulating layer 230, and the first conductive line 210 may be removed using the mask pattern 270 as an etching barrier. Accordingly, an opening OP exposing the substrate 200 may be formed in the first and second peripheral circuit regions PA1 and PA2. As a result of this process, the first conductive line 210 may be cut in the first direction, and it may exist in the cell regions CA while being substantially removed from the first and second peripheral circuit regions PA1 and PA2.

When the opening OP has an inclined sidewall, the third insulating layer 260, the second conductive line 240, the second insulating layer 250, the memory cell 225, the first insulating layer 230, and the first conductive line 210 may not be completely removed in the first and second peripheral circuit regions PA1 and PA2, and portions thereof may remain at the edge of the first and second peripheral circuit regions PA1 and PA2, which is adjacent to the cell region CA. This is not clearly shown in the planar view of FIG. 10A, but is shown in FIGS. 10B and 10C as an example.

For example, as shown in FIG. 10B, in the second direction, a portion of the first conductive line 210, which is closest to the cell region CA, among the first conductive lines 210 of the second peripheral circuit region PA2 may remain in the second peripheral circuit region PA2.

Also, for example, as shown in FIG. 10C, in the first direction, the first conductive line 210 may have an end portion protruding toward the first peripheral circuit region PA1.

The memory device shown in FIGS. 10A, 10B, and 10C may be manufactured by the process described above. Since the second conductive lines 240 may be formed in the cell regions CA as shown in FIG. 7A, rather than in the first and second peripheral circuit regions PA1 and PA2, substantially removing portions of the second conductive lines 240 in the first and second peripheral circuit regions PA1 and PA2 according to the embodiment shown in FIGS. 1A to 5C may be omitted in a manufacturing method of a memory device according to the embodiment of FIGS. 7A to 10C. Accordingly, the manufacturing method of a memory device according to the embodiment of FIGS. 7A to 10C may be simpler than that according to the embodiment of FIGS. 1A to 5C.

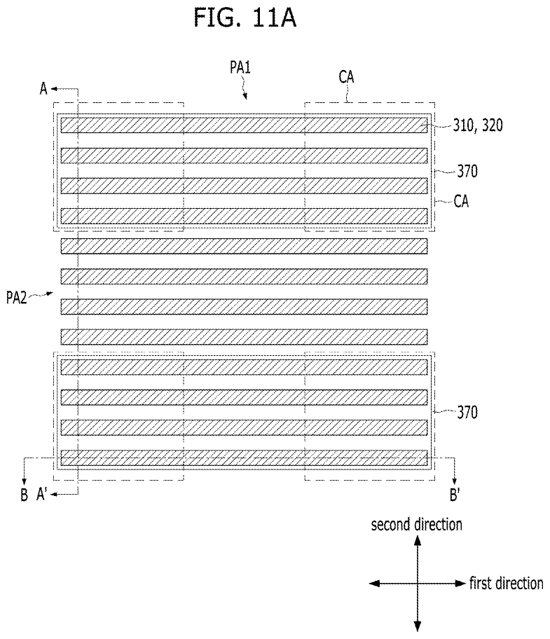

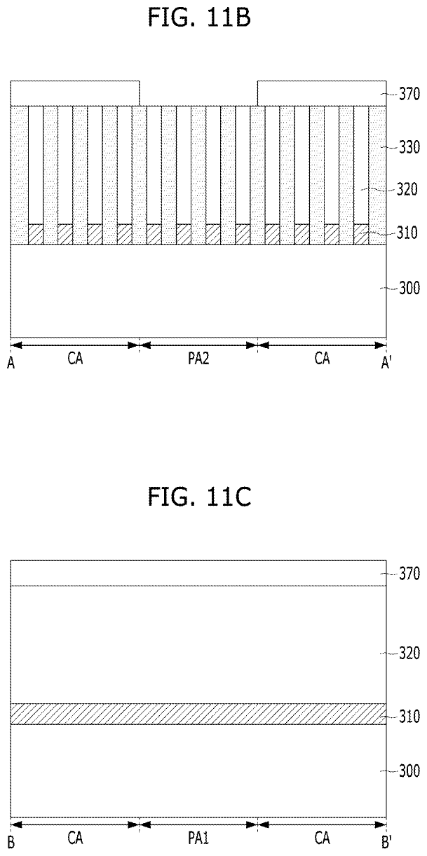

FIGS. 11A to 14C are views illustrating a memory device according to another embodiment of the present disclosure, and a method for manufacturing the same. FIGS. 11A, 12A, 13A, and 14A show planar views, FIGS. 11B, 12B, 13B, and 14B show cross-sectional views taken along a line A-A′ of FIGS. 11A, 12A, 13A, and 14A, respectively, and FIGS. 11C, 12C, 13C, and 14C show cross-sectional views taken along a line B-B′ of FIGS. 11A, 12A, 13A, and 14A, respectively. For convenience of description, conductive lines and memory cells are illustrated in the planar views of FIGS. 11A, 12A, 13A, and 14A, and an insulating layer filling the spaces therebetween is omitted. Differences from the above-described embodiment will be mainly described.

Referring to FIGS. 11A, 11B, and 11C, by performing substantially the same processes as the processes of FIGS. 1A to 2C described above, a structure in which stacked structures of first conductive lines (or initial first conductive lines) 310 and initial memory cells 320 and a first insulating layer (or initial first insulating layer) 330 filled between the stacked structures are formed over the substrate 300 including a cell region CA, a first peripheral circuit region PA1, and a second peripheral circuit region PA2 may be provided. In this case, damage to the initial memory cell 320 may be substantially prevented during the planarization process for forming the first insulating layer 330.

Subsequently, a first mask pattern 370 covering the cell regions CA and the first peripheral circuit region PA1 therebetween while exposing the second peripheral circuit region PA2 may be formed over the initial memory cells 320 and the first insulating layer 330.

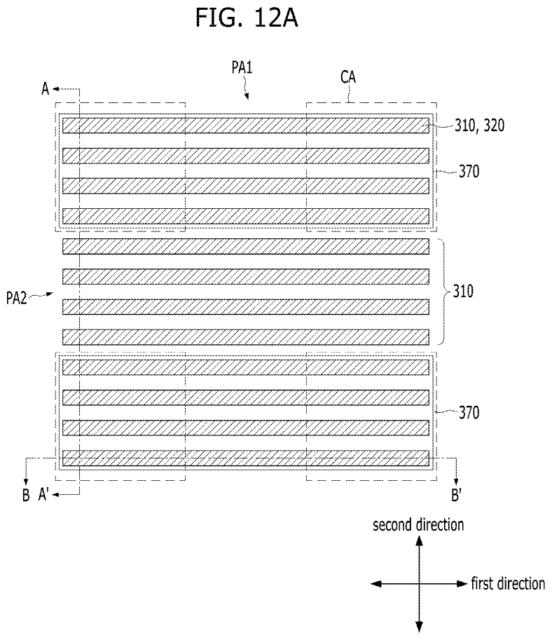

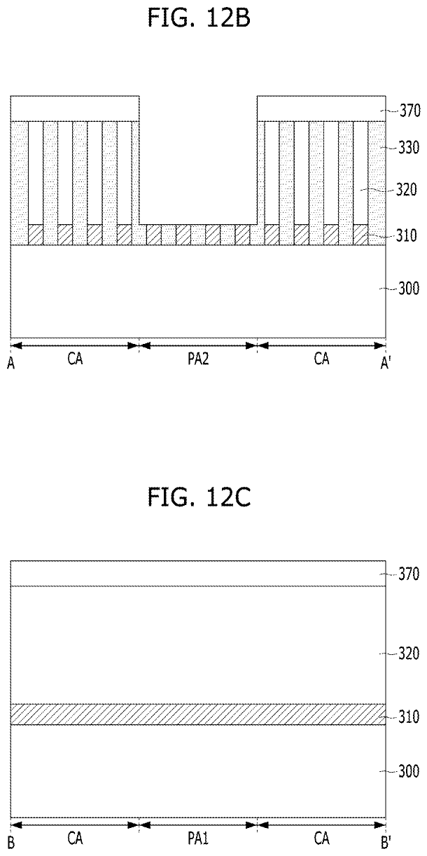

Referring to FIGS. 12A, 12B, and 12C, the initial memory cell 320 and the first insulating layer 330 of the second peripheral circuit region PA2 exposed by the first mask pattern 370 may be removed.

As a result, the first conductive lines 310 and the first insulating layer (or intermediate first insulating layer) 330 therebetween may exist over the substrate 300 in the second peripheral circuit region PA2, and an empty space may be positioned thereon. In the planar view of FIG. 12A, in order to distinguish the stacked structure of the first conductive line 310 and the initial memory cell 320 disposed in the cell region CA and the first peripheral circuit region PA1, the first conductive lines 310 disposed in the second peripheral circuit region PA2 is indicated by enclosing it in braces.

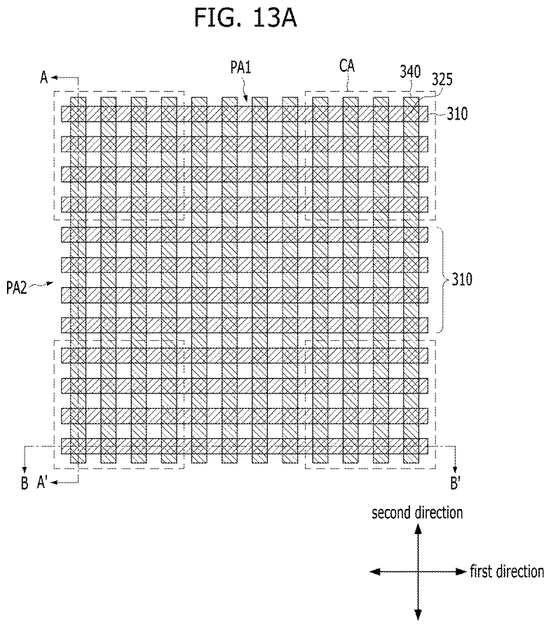

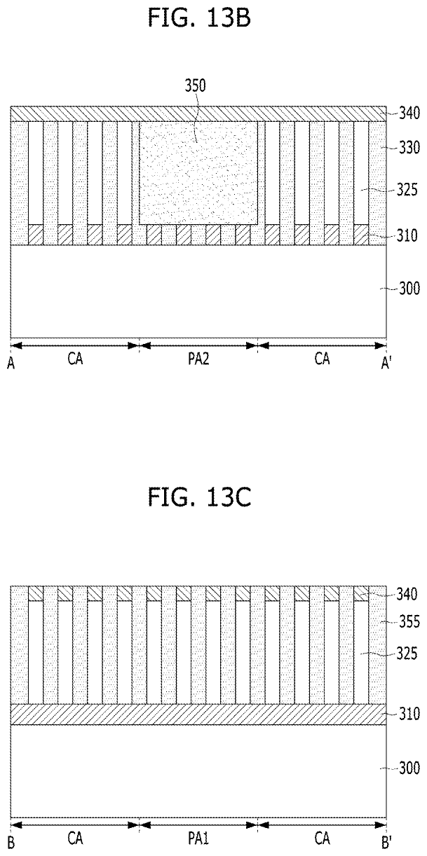

Referring to FIGS. 13A, 13B, and 13C, a second insulating layer (or initial second insulating layer) 350 filling the empty space of the second peripheral circuit region PA2 may be formed.

The second insulating layer 350 may be formed by forming an insulating material with a thickness to sufficiently cover the initial memory cell 320 over the substrate 300, and performing a planarization process until the upper surface of the initial memory cell 320 is exposed. The first mask pattern 370 of FIGS. 12A, 12B, and 12C may be removed through this planarization process or through another process before forming the insulating material for forming the second insulating layer 350.

Since the first conductive lines 310 and the first insulating layer 330 therebetween are present in the second peripheral circuit region PA2, the depression of the second insulating layer 350 and the loss of the initial memory cell 320 therefrom may be reduced, compared to the case in which no pattern is present in the second peripheral circuit region PA2. Specifically, since the initial first conductive lines 310 and the first insulating layer 330 therebetween may be formed in the second peripheral circuit region PA2, the degree of depression of the second insulating layer 350 during the planarization process of forming the second insulating layer 350 may be reduced compared to when the initial first conductive lines 310 are not formed in the second peripheral circuit region PA2 in a conventional manufacturing process. As a result, the degree of loss of the initial memory cell 320 may be reduced in the embodiment shown in FIGS. 13A to 13C compared to that in the conventional manufacturing process.

Subsequently, second conductive lines (or initial second conductive lines) 340 may be formed over the initial memory cell 320, the first insulating layer 330, and the second insulating layer 350.

The second conductive line 340 may have a line shape extending in the second direction and may cross the two cell regions CA arranged in the second direction and the second peripheral circuit region PA2 therebetween. Also, the plurality of second conductive lines 340 may be arranged to be spaced apart from each other in the first direction. In this case, the plurality of second conductive lines 340 in the first direction may exist not only in the cell regions CA but also in the first peripheral circuit region PA1.

Subsequently, memory cells 325 may be formed by etching the initial memory cells 320 exposed by the second conductive lines 340.

In the embodiment of FIGS. 13A to 13C, since the initial memory cell 320 of the second peripheral circuit region PA2 is already removed, the memory cell 325 may not exist in the second peripheral circuit region PA2. That is, although the intersection region of the first conductive line 310 and the second conductive line 340 is shown in the second peripheral circuit region PA2 in the planar view of FIG. 13A, the memory cell 325 may not exist in the intersection region. The memory cell 325 may have an island shape in a planar view while being positioned at the intersection region of the first conductive line 310 and the second conductive line 340 in the cell regions CA and the first peripheral circuit region PA1. The memory cells 325 may be arranged in a matrix form along the first direction and the second direction. Both sidewalls of the memory cell 325 may be aligned with both sidewalls of the second conductive line 340 in the first direction, and both sidewalls of the memory cell 325 may be aligned with both sidewalls of the first conductive line 310 in the second direction.

In the etching process of the initial memory cell 320, the first insulating layer 330 and the second insulating layer 350 exposed by the second conductive lines 340 may be etched together.

Subsequently, a third insulating layer (or an initial third insulating layer) 355 filling spaces between the memory cells 325, between the first insulating layers 330, between the second insulating layers 350, and between the second conductive lines 340 may be formed over the substrate 300.

The third insulating layer 355 may be formed by forming an insulating material with a thickness sufficiently covering the second conductive line 340 over the substrate 300, and performing a is planarization process until the upper surface of the second conductive line 340 is exposed. Since the second conductive line 340 is also present in the first peripheral circuit region PA1, damage to the second conductive line 340 due to a difference in pattern density between the cell region CA and the first peripheral circuit region PA1 during the planarization process may be substantially prevented.

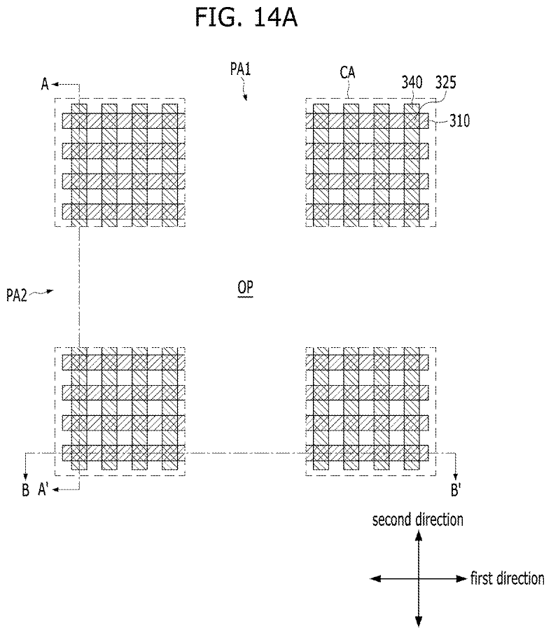

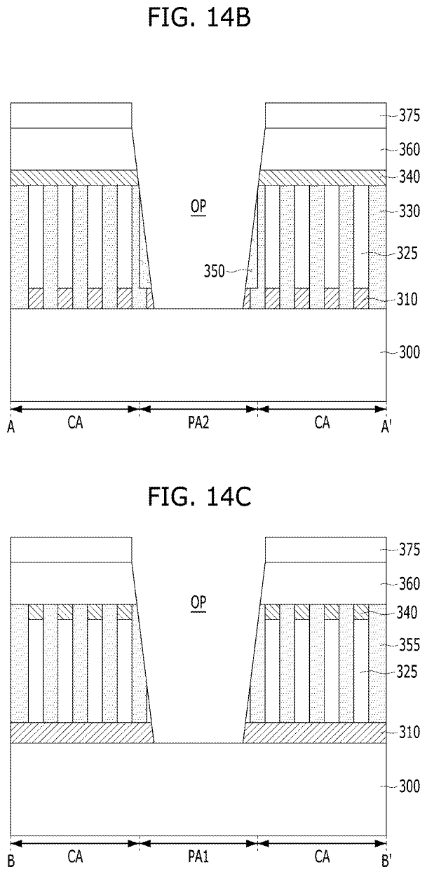

Referring to FIGS. 14A, 14B, and 14C, a fourth insulating layer (or an initial fourth insulating layer) 360 may be formed over the second conductive line 340 and the third insulating layer 355. Then, a second mask pattern 375 may be formed over the fourth insulating layer 360 to cover the cell regions CA and expose the first and second peripheral circuit regions PA1 and PA2. Then, the fourth insulating layer 360, the third insulating layer 355, the second conductive line 340, the second insulating layer 350, the memory cell 325, the first insulating layer 330, and the first conductive line 310 may be removed using the second mask pattern 375 as an etching barrier. Accordingly, an opening OP exposing the substrate 300 may be formed in the first and second peripheral circuit regions PA1 and PA2.

When the opening OP has an inclined sidewall, the fourth insulating layer 360, the third insulating layer 355, the second conductive line 340, the second insulating layer 350, the memory cell 325, the first insulating layer 330, and the first conductive line 310 may not be completely removed in the first and second peripheral circuit regions PA1 and PA2, and portions thereof may remain in the edge of the first and second peripheral circuit regions PA1 and PA2, which is adjacent to the cell region CA. This is not clearly shown in the planar view of FIG. 14A, but is shown in FIGS. 14B and 14C as an example.

For example, as shown in FIG. 14B, in the second direction, a portion of the first conductive line 310, which is closest to the cell region CA, among the first conductive lines 310 of the second peripheral circuit region PA2 may remain in the second peripheral circuit region PA2.

Also, for example, as shown in FIG. 14C, in the first direction, the first conductive line 310 may have an end portion protruding toward the first peripheral circuit region PA1. A portion of memory cell 325 may be present over this end portion.

The memory device shown in FIGS. 14A, 14B, and 14C may be manufactured by the process described above.

According to the above-described embodiments, semiconductor device capable of reducing or substantially preventing damage to a memory cell and a manufacturing method thereof may be provided.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable sub combination. Moreover, although features may be described above as acting in certain combinations and even initially claimed as such, one or more features from a claimed combination can in some cases be excised from the combination, and the claimed combination may be directed to a sub combination or variation of a sub combination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few embodiments and examples are described. Other embodiments, enhancements and variations can be made based on what is described and illustrated in this patent document.

Although various embodiments have been described for illustrative purposes, various changes and modifications may be possible.

What is claimed is:

1. A method for manufacturing a semiconductor device, comprising:
forming a plurality of stacked structures over a substrate, the substrate including one or more peripheral circuit regions and one or more cell regions, the plurality of stacked structures including a plurality of first conductive lines and a plurality of initial memory cells respectively disposed over the first conductive lines, each of the stacked structures extending in a first direction;
forming a first insulating layer between the stacked structures;
forming a plurality of second conductive lines over the stacked structures and the first insulating layer, each of the second conductive lines extending in a second direction that crosses the first direction;
forming memory cells by etching the initial memory cells exposed by the second conductive lines;
forming a second insulating layer between the second conductive lines and between the memory cells; and
removing the first conductive lines, the memory cells, and the second conductive lines in the peripheral circuit regions.

2. The method according to claim 1, wherein the forming of the first insulating layer comprises:
forming an insulating material covering the stacked structures; and
performing a planarization process so that upper surfaces of the stacked structures are exposed,
wherein, in the cell regions and the peripheral circuit regions, the upper surfaces of the stacked structures and an upper surface of the first insulating layer form a substantially flat surface.

3. The method according to claim 1, wherein the forming of the second insulating layer comprises:
forming an insulating material covering the second conductive lines; and
performing a planarization process so that upper surfaces of the second conductive lines are exposed,
wherein, in the cell regions and the peripheral circuit regions, the upper surfaces of the second conductive lines and an upper surface of the second insulating layer form a substantially flat surface.

4. The method according to claim 1, wherein the cell regions are arranged in the first direction and the second direction,
wherein the peripheral circuit regions include a first peripheral circuit region positioned between a first adjacent pair of the cell regions arranged in the first direction, and a second peripheral circuit region positioned between a second adjacent pair of the cell regions arranged in the second direction, and
before removing the first conductive lines, the memory cells, and the second conductive lines in the peripheral circuit regions, the first conductive lines overlap the cell region, the first peripheral circuit region, and the second peripheral circuit region, and the second conductive lines overlap the cell region, the first peripheral circuit region, and the second peripheral circuit region.

5. The method according to claim 4, wherein, in the removing of the first conductive lines, the memory cells, and the second conductive lines in the peripheral circuit regions, at least one of the first conductive lines disposed in the second peripheral circuit region and adjacent to a corresponding one of the cell regions is partially removed.

6. The method according to claim 4, wherein, in the removing of the first conductive lines, the memory cells, and the second conductive lines in the peripheral circuit regions, portions of the first conductive lines in the first peripheral circuit region are removed.

7. A method for manufacturing a semiconductor device, comprising:
forming a plurality of stacked structures over a substrate, the substrate including one or more peripheral circuit regions and one or more cell regions, the plurality of stacked structures including a plurality of first conductive lines and a plurality of initial memory cells respectively disposed over the first conductive lines, each of the stacked structures extending in a first direction;
forming a first insulating layer between the stacked structures;
forming a plurality of second conductive lines over the stacked structures and the first insulating layer, each of the second conductive lines extending in a second direction that crosses the first direction, the second conductive lines overlapping the cell regions without overlapping the peripheral circuit regions;
forming memory cells by etching the initial memory cells exposed by the second conductive lines;
forming a second insulating layer between the second conductive lines and between the memory cells; and
removing the first conductive lines in the peripheral circuit regions.

8. The method according to claim 7, wherein, in the forming of the memory cells, the initial memory cells of the peripheral circuit regions are removed.

9. The method according to claim 7, wherein the forming of the first insulating layer comprises:
forming an insulating material covering the stacked structures; and
performing a planarization process so that upper surfaces of the stacked structures are exposed,
wherein, in the cell regions and the peripheral circuit regions, the upper surfaces of the stacked structures and an upper surface of the first insulating layer form a substantially flat surface.

10. The method according to claim 7, wherein the cell regions are arranged in the first direction and the second direction,
wherein the peripheral circuit regions include a first peripheral circuit region positioned between a first adjacent pair of the cell regions arranged in the first direction and a second peripheral circuit region positioned between a second adjacent pair of the cell regions arranged in the second direction, and
before removing the first conductive lines in the peripheral circuit regions, the first conductive lines overlap the cell region, the first peripheral circuit region, and the second peripheral circuit region.

11. The method according to claim 10, wherein, in the removing of the first conductive lines in the peripheral circuit regions, at least one of the first conductive lines disposed in the second peripheral circuit region and adjacent to a corresponding one of the cell regions is partially removed.

12. The method according to claim 10, wherein, in the removing of the first conductive lines in the peripheral circuit regions, portions of the first conductive lines in the first peripheral circuit region are removed.

13. A method for manufacturing a semiconductor device, comprising:
forming a plurality of stacked structures over a substrate, the substrate including one or more peripheral circuit regions and one or more cell regions, the plurality of stacked structures including a plurality of first conductive lines and a plurality of initial memory cells respectively disposed over the first conductive lines, each of the stacked structures extending in a first direction;
forming a first insulating layer between the stacked structures;
removing a group of the initial memory cells in a specific one of the peripheral circuit regions;
filling a space formed by removing the group of the initial memory cells with a second insulating layer;
forming a plurality of second conductive lines over the stacked structures, the first insulating layer, and the second insulating layer, each of the second conductive lines extending in a second direction that crosses the first direction;
forming memory cells by etching the remaining ones of the initial memory cells exposed by the second conductive lines;
forming a third insulating layer between the second conductive lines and between the memory cells; and
removing the first conductive lines, the memory cells, and the second conductive lines in the peripheral circuit regions.

14. The method according to claim 13, wherein the forming of the first insulating layer comprises:
forming an insulating material covering the stacked structures; and
performing a planarization process so that upper surfaces of the stacked structures are exposed,
wherein, in the cell regions and the peripheral circuit regions, the upper surfaces of the stacked structures and an upper surface of the first insulating layer form a substantially flat surface.

15. The method according to claim 13, wherein the cell regions are arranged in the first direction and the second direction,
wherein the peripheral circuit regions include a first peripheral circuit region positioned between a first adjacent pair of the cell regions arranged in the first direction, and a second peripheral circuit region positioned between a second adjacent pair of the cell regions arranged in the second direction, and
before removing the first conductive lines, the memory cells, and the second conductive lines in the peripheral circuit regions, the first conductive lines overlap the cell region, the first peripheral circuit region, and the second peripheral circuit region, and the second conductive lines overlap the cell region, the first peripheral circuit region, and the second peripheral circuit region.

16. The method according to claim 15, wherein, in the removing of the group of the initial memory cells, the initial memory cells in the second peripheral circuit region are removed.

17. The method according to claim 15, wherein, in the removing of the first conductive lines, the memory cells, and the second conductive lines in the peripheral circuit regions, at least one of the first conductive lines disposed in the second peripheral circuit region and adjacent to a corresponding one of the cell regions is partially removed.

18. The method according to claim 15, wherein, in the removing of the first conductive lines, the memory cells, and the second conductive lines in the peripheral circuit regions, portions of the first conductive lines in the first peripheral circuit region are removed.

19. A semiconductor device comprising:
a substrate including a plurality of cell regions arranged in a first direction and a second direction crossing the first direction, a first peripheral circuit region being positioned between a first adjacent pair of the cell regions arranged in the first direction, a second peripheral circuit region being positioned between a second adjacent pair of the cell regions arranged in the second direction;
a first conductive line disposed over the substrate in a corresponding one of the cell regions and extending in the first direction;
a second conductive line disposed over the first conductive line and extending in the second direction;
a memory cell disposed at an intersection region of the first conductive line and the second conductive line and between the first conductive line and the second conductive line; and
a dummy conductive line disposed in the second peripheral circuit region and adjacent to a corresponding one of the cell regions.

20. The semiconductor device according to claim 19, wherein, in the second direction, a width of the dummy conductive line is smaller than a width of the first conductive line.

21. The semiconductor device according to claim 19, wherein the dummy conductive line has an inclined sidewall.

22. The semiconductor device according to claim 19, the semiconductor memory further comprising:
a dummy memory cell overlapping the dummy conductive line and disposed over the dummy conductive line.

23. The semiconductor device according to claim 22, wherein, in the second direction, a width of the dummy memory cell is smaller than a width of the memory cell.

24. The semiconductor device according to claim 22, wherein the dummy memory cell has an inclined sidewall.

25. The semiconductor device according to claim 19, wherein the first conductive line has an end portion protruding toward the first peripheral circuit region.
